(19) United States
(12) Patent Application Publication
(10) Pub. No.: US 2026/0247565 A1
(43) Pub. Date: Aug. 20, 2026

(54) ASSEMBLIES AND METHODS FOR HYBRID CLAMSHELL IMMERSION AND COLD PLATE COOLING

(71) Applicant: Ciena Corporation, Hanover, MD (US)

(72) Inventors: Roger Paul Toutant, Vernon (CA); Peter Ajersch, Ottawa (CA)

(21) Appl. No.: 19/057,015

(22) Filed: Feb. 19, 2025

(51) Int. Cl. H05K 7/20

(52) U.S. Cl. CPC H05K 7/20236; H05K 7/20254; H05K 7/20772

(57) ABSTRACT

A hybrid clamshell immersion and cold plate cooling assembly and method including and utilizing an immersion clamshell disposed about a component disposed on a printed circuit board, where the immersion clamshell contains an immersion coolant in a high-pressure region and a low-pressure region, and a cooling liquid inlet and a cooling liquid outlet collectively adapted to withdraw immersion coolant from the high-pressure region of the immersion clamshell as a cooling liquid, circulate the cooling liquid to a module disposed external to the immersion clamshell, and return the cooling liquid to the low-pressure region of the immersion clamshell as the immersion coolant.

### TECHNICAL FIELD

The present disclosure relates generally to the telecommunications, networking, and electronics fields. More particularly, the present disclosure relates to assemblies and methods for the hybrid clamshell immersion cooling of a component disposed on a printed circuit board (PCB) and the satellite cold plate cooling of an associated optical module or the like.

### BACKGROUND

Electronic components dissipate heat when operating and sometimes require thermal management to keep them within their recommended thermal operating limits to achieve the greatest reliability and longevity.

Conventional approaches used to cool heat-dissipating electronic components include passive approaches, such as heatsinks and natural convection, and active approaches, such as forced-air cooling using fans. However, there are limits to the effectiveness of forced-air cooling as heat dissipation densities become large. Therefore, more recently, it is not uncommon to see liquid cold plate solutions being employed. Liquid cold plate cooling allows devices to be cooled via a cooling liquid that is circulated through heat transfer cold plates attached to the devices.

Even more recent approaches are being developed that completely immerse PCBs and components, as well as the enclosures or racks in which the PCBs are housed, in a bath of thermal transfer liquid. Such approaches are called immersion cooling. The benefits of immersion cooling include the ability to overcome the limits of forced-air cooling and the simplifying of the potentially complex plumbing of liquid cold plate solutions.

Immersion cooling is not without its drawbacks, however, and can be problematic in several respects. First, the enclosures or racks that are used to house the PCBs are typically laid down in the associated immersion tank which makes access to the sides and bottom of the enclosures or racks challenging. Second, the insertion and removal of the PCBs can require some sort of gantry crane. Third, there are issues related to the personal protective equipment (PPE) sometimes required to allow manual servicing of the hardware in an immersion tank. Fourth, the cleaning of pluggable optical modules (POMs), such as QSFP-DD and OSFP transceivers and the like, is challenging, and the reliability impacts of immersing such devices are not fully understood.

The present background is provided as illustrative environmental context only. It will be readily apparent to those of ordinary skill in the art that the concepts and principles of the present disclosure may be implemented in other environmental contexts equally, without limitation.

### SUMMARY

The present disclosure draws on the benefits of immersion cooling while preventing the entire enclosure or rack and PCB from being fully immersed in an immersion tank. Heat-dissipating components on the primary and/or secondary side of the PCB are enclosed in a sealed clamshell through/within which the immersion coolant flows, thus removing heat from the heat-dissipating components within the clamshell. Further, features may be provided within the clamshell that guide the coolant around the interior of the clamshell (these features may either be part of/attached to the PCB or be part of/attached to the clamshell). Further, satellite cooling connections are provided which permit coolant to flow from the clamshell to cold plates associated with external components, such as adjacent POMs (e.g., QSFP-DD or OSFP optical transceiver devices or the like).

The use of a clamshell to contain the immersion liquid with the use of flow guides within the clamshell and the connection to satellite cold plate-cooled devices make the approach of the present disclosure a hybrid cooling solution.

The flow dividing walls within the clamshell serve to create a high-pressure supply zone and low-pressure return zone. These zones in turn provide the pressure gradient required to drive flow through the liquid-cooled cold plate(s) thermally coupled to the POM(s). One example configuration is a flow distribution manifold disposed inside the immersion clamshell for this purpose.

The connection ports on the immersion clamshell serve to extend its usefulness to beyond the clamshell; i.e. to connect the POM cold plates via piping, tubing, or hosing via fixed connections or quick connect/disconnect connections, accessible or blind-mate, etc.

The electrical subassembly allows power and signals to pass from the wetted immersion zone inside the clamshell to the dry air zone outside the clamshell where the POMs reside.

Thus, the present disclosure overcomes the shortcomings of forced-air cooling, including the cost, noise, and physical limitations imposed by the high heat densities of modern integrated circuits, as well as the shortcomings of cold plate-only solutions, including the complex plumbing required to connect to all heat-dissipating devices on a PCB. The present disclosure also overcomes the shortcomings of conventional liquid immersion, including service complexity and safety. Further, liquid immersion are typically not optimized for optical interconnects because these interconnects are engineered and optimized for low-loss transmission of light through a glass-to-air-to-glass stack-up.

In some embodiments, the present disclosure provides a hybrid clamshell immersion and cold plate cooling assembly including an immersion clamshell disposed about a component disposed on a printed circuit board, where the immersion clamshell contains an immersion coolant in a high-pressure region and a low-pressure region, and a cooling liquid inlet and a cooling liquid outlet collectively adapted to withdraw immersion coolant from the high-pressure region of the immersion clamshell as a cooling liquid, circulate the cooling liquid to a module disposed adjacent to the component and external to the immersion clamshell, and return the cooling liquid to the low-pressure region of the immersion clamshell as the immersion coolant. In some embodiments, the module is disposed on the printed circuit board adjacent to the component and external to the immersion clamshell. In some embodiments, the printed circuit board is disposed entirely within the immersion clamshell. In some embodiments, the high-pressure region of the immersion clamshell includes a high-pressure manifold of the immersion clamshell and the low-pressure region of the immersion clamshell includes a low-pressure manifold of the immersion clamshell. In some embodiments, the hybrid clamshell immersion and cold plate cooling assembly further includes one or more coolant flow guide structures disposed within the immersion clamshell and adapted to guide a flow of the immersion coolant within the immersion clamshell. The cooling liquid inlet and the cooling liquid outlet are collectively adapted to circulate the cooling liquid through a cold plate thermally coupled to the module disposed adjacent to the component and external to the immersion clamshell. In some embodiments, the hybrid clamshell immersion and cold plate cooling assembly further includes one or more leads disposed through the printed circuit board to route high-speed signals from the module the component within the immersion clamshell. Alternatively, in some embodiments, the hybrid clamshell immersion and cold plate cooling assembly further includes a cable routed through the immersion clamshell to route high-speed signals from the module the component within the immersion clamshell. Alternatively, in some embodiments, the hybrid clamshell immersion and cold plate cooling assembly further includes external and internal cables coupled to external and internal connectors of a sealing member disposed through the immersion clamshell to route high-speed signals from the module the component within the immersion clamshell.

In some embodiments, the present disclosure provides a network element including a printed circuit board, a component disposed on the printed circuit board, an immersion clamshell disposed about the component disposed on the printed circuit board, where the immersion clamshell contains an immersion coolant in a high-pressure region and a low-pressure region, a module disposed adjacent to the component and external to the immersion clamshell, and a cooling liquid inlet and a cooling liquid outlet collectively adapted to withdraw immersion coolant from the high-pressure region of the immersion clamshell as a cooling liquid, circulate the cooling liquid to the module disposed adjacent to the component and external to the immersion clamshell, and return the cooling liquid to the low-pressure region of the immersion clamshell as the immersion coolant. In some embodiments, the module is disposed on the printed circuit board adjacent to the component and external to the immersion clamshell. In some embodiments, the printed circuit board is disposed entirely within the immersion clamshell. In some embodiments, the high-pressure region of the immersion clamshell includes a high-pressure manifold of the immersion clamshell and the low-pressure region of the immersion clamshell includes a low-pressure manifold of the immersion clamshell. In some embodiments, the network element further includes one or more coolant flow guide structures disposed within the immersion clamshell and adapted to guide a flow of the immersion coolant within the immersion clamshell. The cooling liquid inlet and the cooling liquid outlet are collectively adapted to circulate the cooling liquid through a cold plate thermally coupled to the module disposed adjacent to the component and external to the immersion clamshell. In some embodiments, the network element further includes one or more leads disposed through the printed circuit board to route high-speed signals from the module the component within the immersion clamshell. Alternatively, in some embodiments, the network element further includes a cable routed through the immersion clamshell to route high-speed signals from the module the component within the immersion clamshell. Alternatively, in some embodiments, the network element further includes external and internal cables coupled to external and internal connectors of a sealing member disposed through the immersion clamshell to route high-speed signals from the module the component within the immersion clamshell.

In some embodiments, the present disclosure provides a hybrid clamshell immersion and cold plate cooling method including, given an immersion clamshell disposed about a component disposed on a printed circuit board, using a cooling liquid inlet and a cooling liquid outlet, withdrawing immersion coolant from a high-pressure region of the immersion clamshell as a cooling liquid, circulating the cooling liquid to a module disposed adjacent to the component and external to the immersion clamshell, and returning the cooling liquid to a low-pressure region of the immersion clamshell as the immersion coolant. In some embodiments, the high-pressure region of the immersion clamshell includes a high-pressure manifold of the immersion clamshell and the low-pressure region of the immersion clamshell includes a low-pressure manifold of the immersion clamshell.

It will be readily apparent to those of ordinary skill in the art that aspects and features of the various described embodiments may be included, omitted, or combined as desired in a given application, without limitation.

### BRIEF DESCRIPTION OF THE DRAWINGS

The present disclosure is illustrated and described with reference to the various drawings, in which like reference numbers are used to denote like assembly components/method steps, as appropriate, and in which:

FIG. 1 is a plan view illustrating one embodiment of the hybrid clamshell immersion and cold plate cooling assembly of the present disclosure;

FIG. 2 is a side view illustrating one embodiment of the hybrid clamshell immersion and cold plate cooling assembly of the present disclosure;

FIG. 3 is a plan view illustrating one embodiment of the hybrid clamshell immersion and cold plate cooling assembly of the present disclosure, highlighting the associated immersion coolant pressure gradient considerations;

FIG. 4 is a plan view illustrating one embodiment of the hybrid clamshell immersion and cold plate cooling assembly of the present disclosure, highlighting one illustrative immersion coolant pressure gradient solution utilizing offset cold plate coolant connections;

FIG. 5 is a plan view illustrating one embodiment of the hybrid clamshell immersion and cold plate cooling assembly of the present disclosure, highlighting another illustrative immersion coolant pressure gradient solution utilizing flow guides disposed within the immersion clamshell;

FIG. 6 is a side view illustrating one embodiment of a high-speed signal routing approach between a POM and a device disposed on a PCB within a localized immersion clamshell for use in conjunction with the hybrid clamshell immersion and cold plate cooling assembly of the present disclosure, highlighting high-speed signal routing through the PCB;

FIG. 7 is a side view illustrating one embodiment of a high-speed signal routing approach between an external POM and a device disposed on a PCB within an all-encompassing immersion clamshell for use in conjunction with the hybrid clamshell immersion and cold plate cooling assembly of the present disclosure, highlighting high-speed signal routing through an external cable;

FIG. 8 is a side view illustrating one embodiment of a high-speed signal routing approach between an external POM and a device disposed on a PCB within an all-encompassing immersion clamshell for use in conjunction with the hybrid clamshell immersion and cold plate cooling assembly of the present disclosure, highlighting high-speed signal routing through internal and external cables and an immersion clamshell interface; and

FIG. 9 is a flowchart illustrating one embodiment of the hybrid clamshell immersion and cold plate cooling method of the present disclosure.

It will be readily apparent to those of ordinary skill in the art that aspects and features of the various illustrated embodiments may be included, omitted, or combined as desired in a given application, without limitation.

### DETAILED DESCRIPTION

Again, the present disclosure draws on the benefits of immersion cooling while preventing the entire enclosure or rack and PCB from being fully immersed in an immersion tank. Heat-dissipating components on the primary and/or secondary side of the PCB are enclosed in a sealed clamshell through/within which the immersion coolant flows, thus removing heat from the heat-dissipating components within the clamshell. Further, features may be provided within the clamshell that guide the coolant around the interior of the clamshell (these features may either be part of/attached to the PCB or be part of/attached to the clamshell). Further, satellite cooling connections are provided which permit coolant to flow from the clamshell to cold plates associated with external components, such as adjacent POMs (e.g., QSFP-DD or OSFP optical transceiver devices or the like).

The use of a clamshell to contain the immersion liquid with the use of flow guides within the clamshell and the connection to satellite cold plate-cooled devices make the approach of the present disclosure a hybrid cooling solution.

The flow dividing walls within the clamshell serve to create a high-pressure supply zone and low-pressure return zone. These zones in turn provide the pressure gradient required to drive flow through the liquid-cooled cold plate(s) thermally coupled to the POM(s). One example configuration is a flow distribution manifold disposed inside the immersion clamshell for this purpose.

The connection ports on the immersion clamshell serve to extend its usefulness to beyond the clamshell; i.e. to connect the POM cold plates via piping, tubing, or hosing via fixed connections or quick connect/disconnect connections, accessible or blind-mate, etc.

The electrical subassembly allows power and signals to pass from the wetted immersion zone inside the clamshell to the dry air zone outside the clamshell where the POMs reside.

Thus, the present disclosure overcomes the shortcomings of forced-air cooling, including the cost, noise, and physical limitations imposed by the high heat densities of modern integrated circuits, as well as the shortcomings of cold plate-only solutions, including the complex plumbing required to connect to all heat-dissipating devices on a PCB. The present disclosure also overcomes the shortcomings of conventional liquid immersion, including service complexity and safety. Further, liquid immersion are typically not optimized for optical interconnects because these interconnects are engineered and optimized for low-loss transmission of light through a glass-to-air-to-glass stack-up.

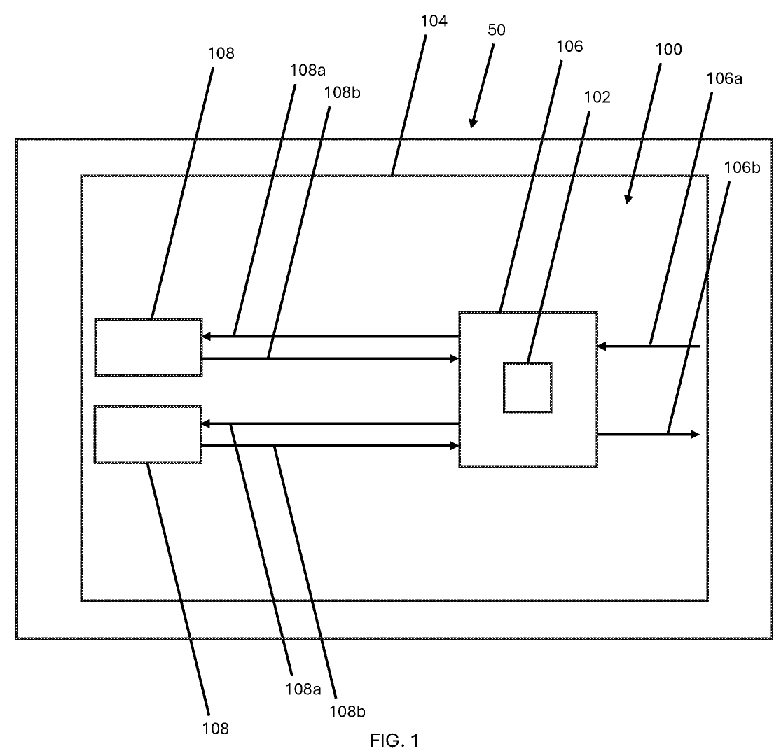

Referring to FIG. 1, in one embodiment, the hybrid clamshell immersion and cold plate cooling assembly 100 of the present disclosure includes a component 102 disposed on a PCB 104. The component 102 is a heat-dissipating electronic device or structure that it is desirable to cool by immersion cooling. Accordingly, an immersion clamshell 106 is disposed over/about and surrounds the component 102 on the PCB 104. One or more modules 108 that it is desirable to cool by liquid cooling are disposed on or adjacent to the PCB 104 adjacent to the component 102 but outside of the immersion clamshell 106. For example, the one or more modules 108 may be one or more optical modules, POMs and cages, or the like, each with an associated cold plate. Immersion coolant is introduced into and removed from the immersion clamshell 106 via an immersion coolant inlet 106a and an immersion coolant outlet 106b. The immersion coolant is circulated to each of the one or more modules 108 as (cold plate) cooling liquid via a cooling liquid inlet 108a and cooling liquid outlet 108b. Thus, at the component 102 and within the immersion clamshell 106, the coolant serves as a thermal immersion liquid, while at each of the one or more modules 108 outside of the immersion clamshell 106, the same coolant serves a (cold plate) cooling liquid – providing the hybrid clamshell immersion and cold plate cooling assembly 100. All of the components of all embodiments may be provided as part of a network element 50, which may take the form of a rack element, a module, a blade, etc., well known to those of ordinary skill in the art.

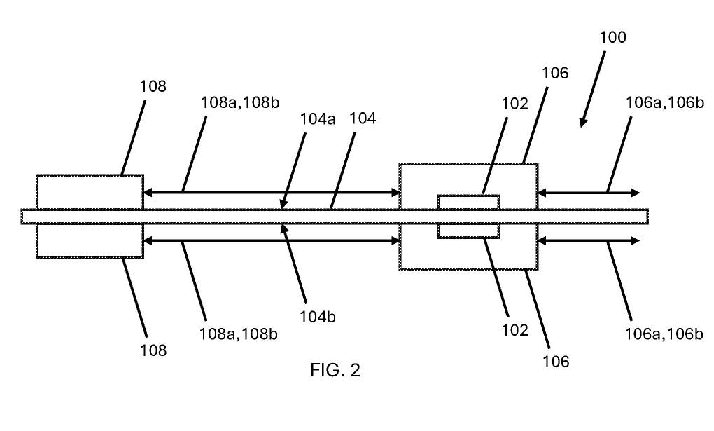

Referring to FIG. 2, in one embodiment, the hybrid clamshell immersion and cold plate cooling assembly 100 of the present disclosure includes a component 102 disposed on each of a primary surface 104a and a secondary surface 104b of a PCB 104. Alternatively, a single component 102 is disposed through the PCB 104 and is exposed on both the primary surface 104a and the secondary surface 104b of the PCB 104. Again, the components 102 are heat-dissipating electronic devices or structures that are desirable to cool by immersion cooling. Accordingly, an immersion clamshell 106 is disposed over/about and surrounds each of the components 102 on the PCB 104. These immersion clamshells 106 (primary side and secondary side) may be independent immersion clamshells 106 or they may be primary and secondary halves of an immersion clamshell assembly 106. One or more modules 108 that it is desirable to cool by liquid cooling are disposed on or adjacent to the PCB 104 adjacent to the components 102 but outside of the immersion clamshells 106 on each of the primary side 104a and the secondary side 104b of the PCB 104. For example, the one or more modules 108 may be one or more optical modules, POMs and cages, or the like, each with an associated cold plate disposed in a primary side-secondary side belly-to-belly configuration. Again, immersion coolant is introduced into and removed from the immersion clamshells 106 via immersion coolant inlets 106a and an immersion coolant outlets 106b, which may be consolidated, combined, or joined as desired. The immersion coolant is circulated to each of the one or more modules 108 as (cold plate) cooling liquid via a cooling liquid inlet 108a and cooling liquid outlet 108b. Thus, at the components 102 and within the immersion clamshells 106, the coolant serves as a thermal immersion liquid, while at each of the one or more modules 108 outside of the immersion clamshells 106, the same coolant serves a (cold plate) cooling liquid – again providing the hybrid clamshell immersion and cold plate cooling assembly 100, but this time in a dual-side configuration.

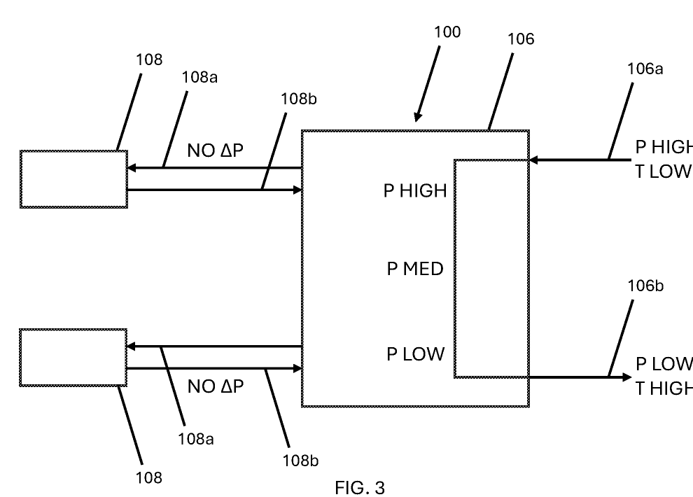

As illustrated in FIG. 3, for a given immersion clamshell 106, the pressure is high and the temperature is low at the immersion coolant inlet 106a while the pressure is low and the temperature is high at the immersion coolant outlet 106b, with a medium pressure and temperature and pressure and temperature gradients between the immersion coolant inlet 106a and the immersion coolant outlet 106b, as the immersion coolant circulates and cools the associated component 102. If for each module 108 the cooling liquid inlet 108a and the cooling liquid outlet 108b are collocated with respect to their interfaces with the immersion clamshell 106, then no pressure differential exists between the cooling liquid inlet 108a and the cooling liquid outlet 108b and cooling liquid will not flow to, through, or out of the cold plate of the module 108. With respect to the cold plate of the module 108, there is no pressure gradient to drive the cooling liquid from the immersion clamshell 106. As is illustrated, one module 108 may inlet from and exit only to a high-pressure area of the immersion clamshell 106, while another module 108 may inlet from an exit to only a low-pressure area of the immersion clamshell 106. This eliminates any option of effectively running a liquid cooling circuit from the immersion clamshell 106.

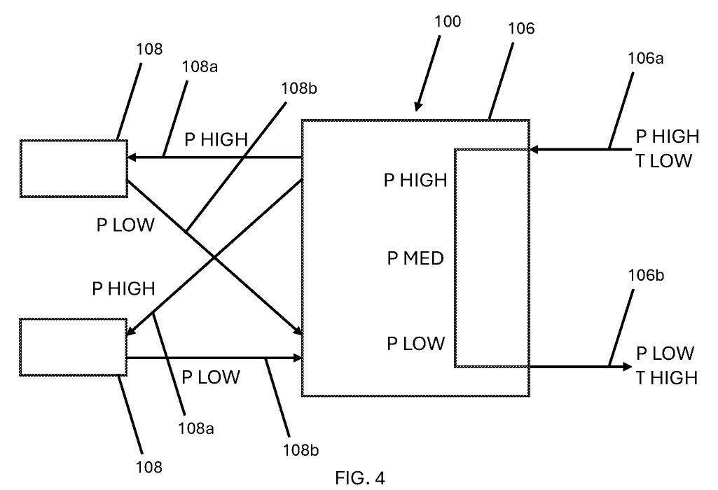

Referring to FIG. 4, in one embodiment, again for a given immersion clamshell 106, the pressure is high and the temperature is low at the immersion coolant inlet 106a while the pressure is low and the temperature is high at the immersion coolant outlet 106b, with a medium pressure and temperature and pressure and temperature gradients between the immersion coolant inlet 106a and the immersion coolant outlet 106b, as the immersion coolant circulates and cools the associated component 102. Here, for each module 108, the cooling liquid inlet 108a interfaces the immersion clamshell 106 at a high-pressure region within the immersion clamshell 106 and the cooling liquid outlet 108b interfaces the immersion clamshell 106 at a low-pressure region within the immersion clamshell 106. Thus, cooling liquid will flow to, through, and out of the cold plate of the module 108 due to the inlet-to-outlet pressure differential for each. With respect to the cold plate of the module 108, there is now a pressure gradient and differential to drive the cooling liquid from the immersion clamshell 106. The greater the pressure gradient and differential, the greater the flow through each module 108. This enables effectively running a liquid cooling circuit from the immersion clamshell 106.

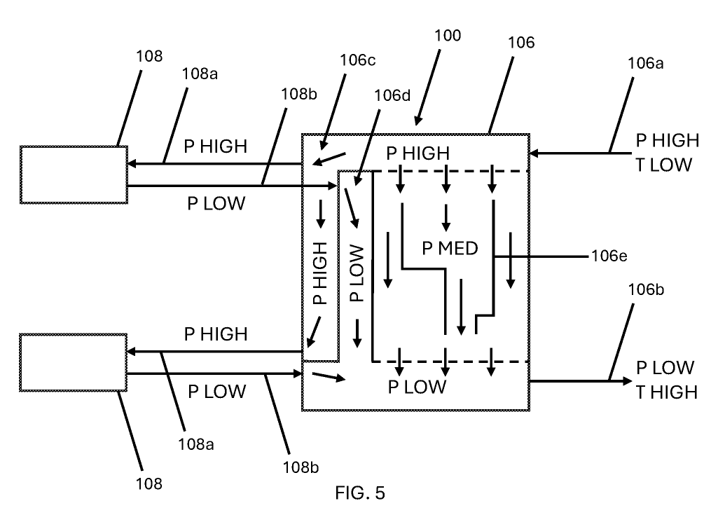

Referring to FIG. 5, in one embodiment, again for a given immersion clamshell 106, the pressure is high and the temperature is low at the immersion coolant inlet 106a while the pressure is low and the temperature is high at the immersion coolant outlet 106b, with a medium pressure and temperature and pressure and temperature gradients between the immersion coolant inlet 106a and the immersion coolant outlet 106b, as the immersion coolant circulates and cools the associated component 102. In this embodiment, a high-pressure manifold 106c is formed within the immersion clamshell 106. Likewise, a low-pressure manifold 106d is formed within the immersion clamshell 106. Further, one or more coolant flow guide structures 106e may be disposed within the immersion clamshell 106. The high-pressure manifold 106c, the low-pressure manifold 106d, and the coolant flow guide structures 106e may be disposed on or coupled to the PCB 104 or may be integrally formed with or coupled to the immersion clamshell 106. The coolant flow guide structures 106e may act to route coolant to the high-pressure manifold 106c or deliver coolant to the low-pressure manifold 106d, and/or they may enhance the pressure gradient within the immersion clamshell 106, and/or they may reduce turbulence within the immersion clamshell 106. The coolant flow guide structures 106e may include walls, vanes, pins, protrusions, constriction areas, relief areas, etc. Here, for each module 108, the cooling liquid inlet 108a interfaces the immersion clamshell 106 at the high-pressure manifold 106c within the immersion clamshell 106 and the cooling liquid outlet 108b interfaces the immersion clamshell 106 at the low-pressure manifold 106d within the immersion clamshell 106. Thus, cooling liquid will flow to, through, and out of the cold plate of the module 108 due to the inlet-to-outlet pressure differential for each based on the coolant pressure in each of the manifolds 106c,106d. With respect to the cold plate of the module 108, there is again now a pressure gradient and differential to drive the cooling liquid from the immersion clamshell 106. The greater the pressure gradient and differential, the greater the flow through each module 108. This again enables effectively running a liquid cooling circuit from the immersion clamshell 106. It should be noted that the manifolds 106c,106d and the coolant flow guide structures 106e may be used individually and do not have to be used in combination as illustrated. For example, the high-pressure manifold 106c and the low-pressure manifold 106d may be stacked structures within the immersion clamshell 106, providing differential pressures as the coolant spirals through or travels vertically within the immersion clamshell 106.

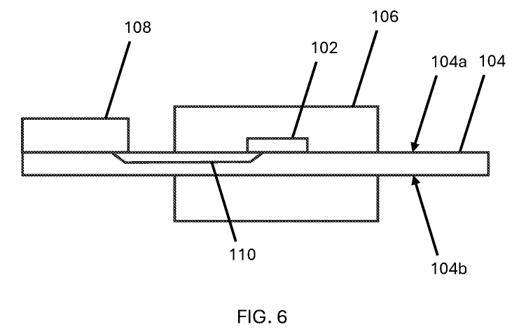

Referring to FIG. 6, in one embodiment, high-speed signals are routed from the module 108 to the component 102 within the immersion clamshell 106 via one or more leads 110 that are disposed through the PCB 104. In the embodiment illustrated, the module 108 is disposed on or coupled to the PCB 104. This arrangement may be used for modules 108 disposed on either or both of the primary surface 104a and the secondary surface 104b of the PCB 104. This arrangement implicates immersion coolant sealing only between the immersion clamshell 106, the component 102, and the PCB 104, as the leads 110 do not pass through the structure of the immersion clamshell 106 itself. It should be noted that the immersion coolant conduits are omitted from this figure for the sake of clarity.

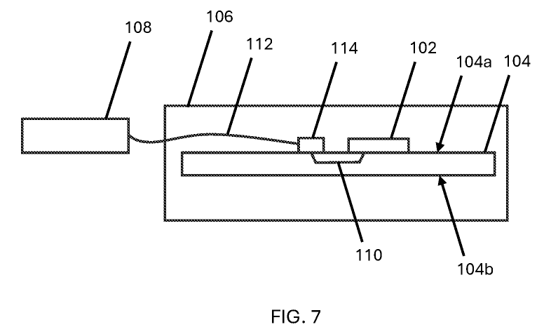

Referring to FIG. 7, in one embodiment, high-speed signals are routed from the module 108 to the component 102 within the immersion clamshell 106 via a cable 112 that is disposed through the structure of the immersion clamshell 106. Here, the cable 112 is routed to a connector 114 associated with the component 102. For example, the connector 114 may be coupled to the component 102 via one or more leads 110 that are disposed through the PCB 104 within the immersion clamshell 106. In the embodiment illustrated, the module 108 is external and is not disposed on the PCB 104, which is enveloped within the immersion clamshell 106. The module 108 could instead be disposed on the PCB 104 external to the immersion clamshell 106, still using the cable 112 for the high-speed signals, but using one or more leads disposed through the PCB 104 for low-speed signal routing. Again, this arrangement may be used for modules 108 associated with either or both of the primary surface 104a and the secondary surface 104b of the PCB 104. This arrangement implicates immersion coolant sealing between the cable 112 and the immersion clamshell 106, as well as between the immersion clamshell 106 and the PCB 104, if the leads 110 pass through the PCB 104 between the connector 114 and the component 102. It should again be noted that the immersion coolant conduits are omitted from this figure for the sake of clarity.

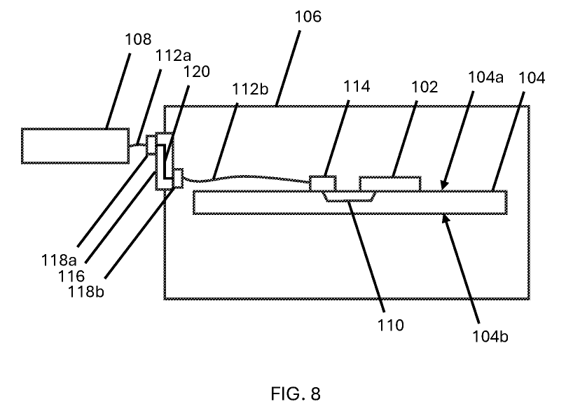

Referring to FIG. 8, in one embodiment, high-speed signals are routed from the module 108 to the component 102 within the immersion clamshell 106 via an external cable 112a disposed outside of the immersion clamshell 106 and an internal cable 112b disposed inside of the immersion clamshell 106, both of which are routed to a sealing member 116 disposed in the structure of the immersion clamshell 106. More specifically, the external cable 112a is routed to an external connector 118a of the sealing member 116 disposed outside of the immersion clamshell 106, and the internal cable 112b is routed to an internal connector 118b of the sealing member 116 disposed inside of the immersion clamshell 106. The external connector 118a is coupled to the internal connector 118b via a connector 120 of the sealing member 116 at the structure of the immersion clamshell 106. The internal cable 112b is then routed to the connector 114 associated with the component 102 within the immersion clamshell 106. For example, the connector 114 may be coupled to the component 102 via one or more leads 110 that are disposed through the PCB 104 within the immersion clamshell 106. In the embodiment illustrated, the module 108 is external and is not disposed on the PCB 104, which is enveloped within the immersion clamshell 106. The module 108 could instead be disposed on the PCB 104 external to the immersion clamshell 106, still using the cables 112a,112b for the high-speed signals, but using one or more leads disposed through the PCB 104 for low-speed signal routing. Again, this arrangement may be used for modules 108 associated with either or both of the primary surface 104a and the secondary surface 104b of the PCB 104. This arrangement implicates immersion coolant sealing between the sealing member 116 and the immersion clamshell 106 (with the sealing member 116 acting as a “patch” in the structure of the immersion clamshell 106), as well as between the immersion clamshell 106 and the PCB 104, if the leads 110 pass through the PCB 104 between the connector 114 and the component 102. It should again be noted that the immersion coolant conduits are omitted from this figure for the sake of clarity.

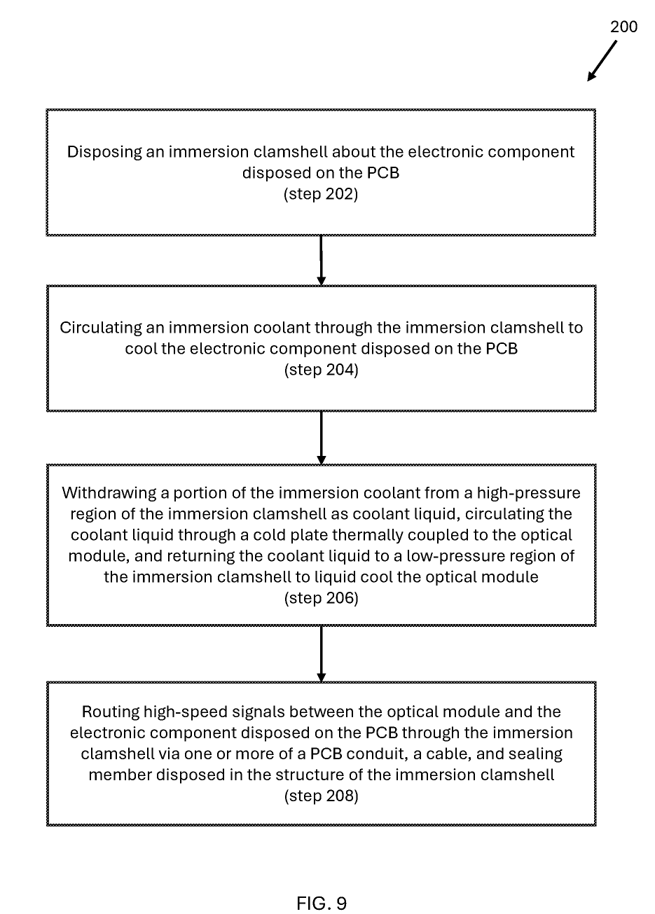

Referring to FIG. 9, in one embodiment, a method 200 for cooling an electronic component disposed on a PCB and an adjacent optical module includes disposing an immersion clamshell about the electronic component disposed on the PCB (step 202) and circulating an immersion coolant through the immersion clamshell to cool the electronic component disposed on the PCB (step 204). The method 200 further includes withdrawing a portion of the immersion coolant from a high-pressure region of the immersion clamshell as coolant liquid, circulating the coolant liquid through a cold plate thermally coupled to the optical module, and returning the coolant liquid to a low-pressure region of the immersion clamshell to liquid cool the optical module (step 206). As mentioned above, the high-pressure region of the immersion clamshell may be a high-pressure manifold of the immersion clamshell, and the low-pressure region of the immersion clamshell may be a low-pressure manifold of the immersion clamshell. The method 200 further includes routing high-speed signals between the optical module and the electronic component disposed on the PCB through the immersion clamshell via one or more of a PCB conduit, a cable, and sealing member disposed in the structure of the immersion clamshell (step 208).

Again, the present disclosure draws on the benefits of immersion cooling while preventing the entire enclosure or rack and PCB from being fully immersed in an immersion tank. Heat-dissipating components on the primary and/or secondary side of the PCB are enclosed in a sealed clamshell through/within which the immersion coolant flows, thus removing heat from the heat-dissipating components within the clamshell. Further, features may be provided within the clamshell that guide the coolant around the interior of the clamshell (these features may either be part of/attached to the PCB or be part of/attached to the clamshell). Further, satellite cooling connections are provided which permit coolant to flow from the clamshell to cold plates associated with external components, such as adjacent POMs (e.g., QSFP-DD or OSFP optical transceiver devices or the like).

The use of a clamshell to contain the immersion liquid with the use of flow guides within the clamshell and the connection to satellite cold plate-cooled devices make the approach of the present disclosure a hybrid cooling solution.

Although the present disclosure is illustrated and described with reference to illustrative embodiments and examples, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following non-limiting claims for all purposes.

What is claimed is:

1. A hybrid clamshell immersion and cold plate cooling assembly comprising
an immersion clamshell disposed about a component disposed on a printed circuit board, wherein the immersion clamshell contains an immersion coolant in a high-pressure region and a low-pressure region, and
a cooling liquid inlet and a cooling liquid outlet collectively adapted to withdraw immersion coolant from the high-pressure region of the immersion clamshell as a cooling liquid, circulate the cooling liquid to a module disposed external to the immersion clamshell, and return the cooling liquid to the low-pressure region of the immersion clamshell as the immersion coolant.

2. The hybrid clamshell immersion and cold plate cooling assembly of claim 1, wherein the module is disposed on the printed circuit board external to the immersion clamshell.

3. The hybrid clamshell immersion and cold plate cooling assembly of claim 1, wherein the printed circuit board is disposed entirely within the immersion clamshell.

4. The hybrid clamshell immersion and cold plate cooling assembly of claim 1, wherein the high-pressure region of the immersion clamshell comprises a high-pressure manifold of the immersion clamshell and the low-pressure region of the immersion clamshell comprises a low-pressure manifold of the immersion clamshell.

5. The hybrid clamshell immersion and cold plate cooling assembly of claim 1, further comprising one or more coolant flow guide structures disposed within the immersion clamshell and adapted to guide a flow of the immersion coolant within the immersion clamshell.

6. The hybrid clamshell immersion and cold plate cooling assembly of claim 1, wherein the cooling liquid inlet and the cooling liquid outlet are collectively adapted to circulate the cooling liquid through a cold plate thermally coupled to the module disposed external to the immersion clamshell.

7. The hybrid clamshell immersion and cold plate cooling assembly of claim 1, further comprising one or more leads disposed through the printed circuit board to route high-speed signals from the module the component within the immersion clamshell.

8. The hybrid clamshell immersion and cold plate cooling assembly of claim 1, further comprising a cable routed through the immersion clamshell to route high-speed signals from the module the component within the immersion clamshell.

9. The hybrid clamshell immersion and cold plate cooling assembly of claim 1, further comprising external and internal cables coupled to external and internal connectors of a sealing member disposed through the immersion clamshell to route high-speed signals from the module the component within the immersion clamshell.

10. A network element comprising
a printed circuit board,
a component disposed on the printed circuit board,
an immersion clamshell disposed about the component disposed on the printed circuit board, wherein the immersion clamshell contains an immersion coolant in a high-pressure region and a low-pressure region,
a module disposed external to the immersion clamshell, and
a cooling liquid inlet and a cooling liquid outlet collectively adapted to withdraw immersion coolant from the high-pressure region of the immersion clamshell as a cooling liquid, circulate the cooling liquid to the module disposed external to the immersion clamshell, and return the cooling liquid to the low-pressure region of the immersion clamshell as the immersion coolant.

11. The network element of claim 10, wherein the module is disposed on the printed circuit board external to the immersion clamshell.

12. The network element of claim 10, wherein the printed circuit board is disposed entirely within the immersion clamshell.

13. The network element of claim 10, wherein the high-pressure region of the immersion clamshell comprises a high-pressure manifold of the immersion clamshell and the low-pressure region of the immersion clamshell comprises a low-pressure manifold of the immersion clamshell.

14. The network element of claim 10, further comprising one or more coolant flow guide structures disposed within the immersion clamshell and adapted to guide a flow of the immersion coolant within the immersion clamshell.

15. The network element of claim 10, wherein the cooling liquid inlet and the cooling liquid outlet are collectively adapted to circulate the cooling liquid through a cold plate thermally coupled to the module disposed external to the immersion clamshell.

16. The network element of claim 10, further comprising one or more leads disposed through the printed circuit board to route high-speed signals from the module the component within the immersion clamshell.

17. The network element of claim 10, further comprising a cable routed through the immersion clamshell to route high-speed signals from the module the component within the immersion clamshell.

18. The network element of claim 10, further comprising external and internal cables coupled to external and internal connectors of a sealing member disposed through the immersion clamshell to route high-speed signals from the module the component within the immersion clamshell.

19. A hybrid clamshell immersion and cold plate cooling method comprising
given an immersion clamshell disposed about a component disposed on a printed circuit board, using a cooling liquid inlet and a cooling liquid outlet, withdrawing immersion coolant from a high-pressure region of the immersion clamshell as a cooling liquid, circulating the cooling liquid to a module disposed external to the immersion clamshell, and returning the cooling liquid to a low-pressure region of the immersion clamshell as the immersion coolant.

20. The hybrid clamshell immersion and cold plate cooling method of claim 19, wherein the high-pressure region of the immersion clamshell comprises a high-pressure manifold of the immersion clamshell and the low-pressure region of the immersion clamshell comprises a low-pressure manifold of the immersion clamshell.
